(19) United States
(12) Patent Application Publication
(10) Pub. No.: US 2021/0242373 A1
(43) Pub. Date: Aug. 5, 2021

(54) CHIP ON BOARD DISPLAY DEVICE AND METHOD FOR MAKING THE SAME

(71) Applicant: MACROBLOCK, INC., Hsinchu (TW)

(72) Inventors: Shih-Sian Liang, Hsinchu (TW); Wei-Ming Tseng, Hsinchu (TW)

(73) Assignee: MACROBLOCK, INC., Hsinchu (TW)

(21) Appl. No.: 17/163,750

(22) Filed: Feb. 1, 2021

(30) Foreign Application Priority Data
Feb. 5, 2020 (TW) 109103482

(51) Int. Cl. H01L 33/48; H01L 25/075; H01L 33/58; H01L 33/62; H01L 33/00; G02B 1/11

(52) U.S. Cl. CPC H01L 33/486; H01L 25/0753; H01L 33/58; H01L 2933/0066; H01L 33/005; G02B 1/11; H01L 2933/0058; H01L 33/62

(57) ABSTRACT

A chip on board (COB) display device includes a substrate, an array of spaced-apart micro light-emitting diode (LED) chips, a light-shielding layer, and an anti-glare layer. The micro LED chips are disposed on the substrate to define thereamong, a recessed portion recessed relative to the micro LED chips. The light-shielding layer is filled in the recessed portion. The anti-glare layer is disposed to cover the light-shielding layer and the micro LED chips, and has a surface which is opposite to the substrate and which is formed with a patterned microstructure. A method for making the COB display device is also disclosed herein.

### CROSS-REFERENCE TO RELATED APPLICATION

This application claims priority of Taiwanese Invention Patent Application No. 109103482, filed on Feb. 5, 2020.

### FIELD

The disclosure relates to a display device and a method for making the same, and more particularly to a chip on board (COB) display device and a method for making the same.

### BACKGROUND

With a growing trend in development of light-emitting devices with improved properties, such as a lighter weight, a thinner dimension, and a higher luminance, and so on, a surface-mount technology (SMT) may no longer satisfy the requirements for current light-emitting devices. Therefore, a chip on board (COB) packaging technology is now used for making light-emitting devices.

A COB light-emitting diode (LED) display may be made by mounting a plurality of LED dies directly on, for example, a circuit board, so as to be electrically connected to the circuit board, and then encapsulating the LED dies on the circuit board using an encapsulant. Such COB LED display has an improved heat dissipating capability and a higher luminous flux.

### SUMMARY

An object of the disclosure is to provide a novel chip on board (COB) display device with an anti-glare property. A method for making the COB display device is also provided.

According to a first aspect of the disclosure, a COB display device includes a substrate, an array of spaced-apart micro light-emitting diode (LED) chips, a light-shielding layer, and an anti-glare layer.

The substrate includes a first surface and a second surface that are opposite to each other.

The micro LED chips are disposed on the first surface of the substrate to define thereamong, a recessed portion recessed relative to the micro LED chips.

The light-shielding layer is made of an opaque polymer material. The light-shielding layer is disposed on the first surface and is filled in the recessed portion.

The anti-glare layer is made of a light-transmissive optical material. The anti-glare layer is disposed to cover the light-shielding layer and the micro LED chips, and has a surface which is opposite to the substrate and which is formed with a patterned microstructure.

According to a second aspect of the disclosure, a method for making a COB display device includes the steps of:

a) mounting an array of spaced-apart micro light-emitting diode (LED) chips on a first surface of a substrate to permit the micro LED chips to define thereamong, a recessed portion;

b) filling an opaque polymer material in the recessed portion by inkjet printing to form a light-shielding layer therein, so as to obtain a semi-finished product;

c) providing a mold with a mold-releasing layer which has a micropattern of a concave-convex structure and which is provided for confronting the micro LED chips of the semi-finished product;

d) positioning the semi-finished product in a mold cavity of the mold in such a manner that the micro LED chips faces the mold-releasing layer; and

e) after step d), introducing a light-transmissive optical material to the mold cavity that is positioned between the semi-finished product and the mold-releasing layer, such that the light-transmissive optical material is cured to form an anti-glare layer that covers the light-shielding layer and the micro LED chips, and such that the micropattern of the mold-releasing layer is transferred to form a patterned microstructure of the anti-glare layer.

### BRIEF DESCRIPTION OF THE DRAWINGS

Other features and advantages of the disclosure will become apparent in the following detailed description of the embodiments with reference to the accompanying drawings, of which:

FIG. 1 shows a schematic side view of an embodiment of a chip on board (COB) display device according to the disclosure;

FIG. 2 is a flow chart illustrating consecutive steps of a method for making the COB display device; and

FIG. 3 shows schematic side views illustrating the consecutive steps of the method.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

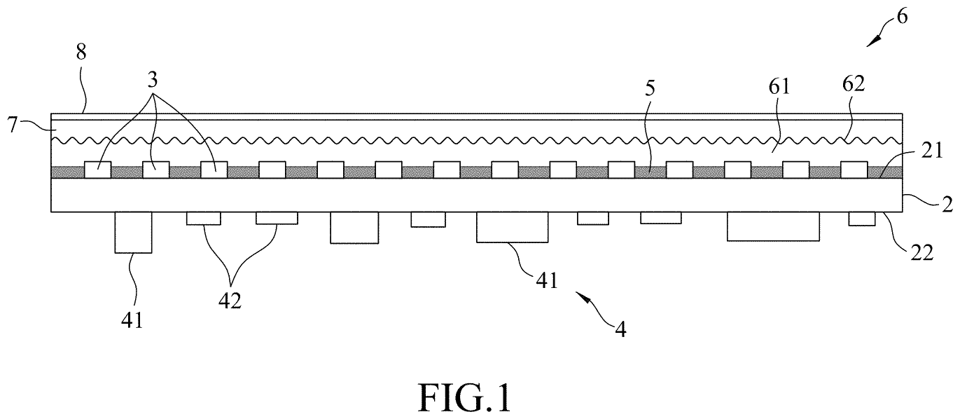

Referring to FIG. 1, a chip on board (COB) display device according to an embodiment of the disclosure is shown to include a substrate 2, micro light-emitting diode (LED) chips 3, an electronic component unit 4, a light-shielding layer 5, an anti-glare layer 6, an anti-reflection layer 7, and an anti-fingerprint layer 8.

The substrate 2 may be made of a light-transmissive material (e.g., a glass) or an opaque material (e.g., a ceramic), and may be a circuit board having a control circuit. The substrate 2 includes a first surface 21 and a second surface 22 that are opposite to each other. In this embodiment, the substrate 2 is exemplified as a glass substrate, and has a circuit provided thereon (not shown) for electrically connecting to the micro LED chips 3 and the electronic component unit 4.

The micro LED chips 3 may be a plurality of dies that can emit lights having the same color or different colors. The micro LED chips 3 are disposed on the first surface 21 of the substrate 2 in an array, and are spaced apart from each other to define thereamong, a recessed portion recessed relative to the micro LED chips 3. To be specific, the micro LED chips 3 are directly soldered on the first surface 21 of the substrate 2 through a solder material (not shown), and are electrically connected to the circuit of the substrate 2. In an embodiment, the micro LED chips 3 may include, for example, red micro LED chips that can emit red lights, green micro LED chips that can emit green lights, and blue micro LED chips that can emit blue lights.

The electronic component unit 4 may include a plurality of electronic components such as active elements 41 (e.g., transistors or rectifiers) and/or passive elements 42 (e.g., resistors, capacitors, or inductors). The electronic components are disposed on the second surface 22 of the substrate 2 and are in signal connection with at least one portion of the micro LED chips 3. Specifically, the electronic components may be electrically connected to the at least one portion of the micro LED chips 3 through the circuit, so as to control the at least one portion of the micro LED chips 3 and to permit the at least one portion of the micro LED chips 3 to be electrically connected to an external control circuit (not shown).

The light-shielding layer 5 is made of an opaque polymer material, and is disposed on the first surface 21 to be filled in the recessed portion.

Specifically, the light-shielding layer 5 may be a commonly used black matrix resin (BM), and may be filled to a level not higher than that of the micro LED chips 3. By virtue of filling the light-shielding layer 5 in the recessed portion, lights emitted from the adjacent micro LED chips 3 can be prevented from interfering with each other, thereby increasing the light-emitting efficiency thereof.

The anti-glare layer 6 is disposed to cover the light-shielding layer 5 and the micro LED chips 3. The anti-glare layer 6 has a light-transmissive body 61 made of a light-transmissive optical material, and has a surface which is opposite to the substrate 2 and which is formed with a patterned microstructure 62. The patterned microstructure 62 may be a regular or irregular concave-convex pattern that is evenly distributed on the surface of the anti-glare layer 6. The patterned microstructure 62 is conducive for scattering lights in contact therewith, so as to reduce reflection of lights.

The anti-reflection layer 7 may be made of a light-transmissive material that has a refractive index (denoted by n) ranging between that of a semiconductor material for making the micro LED chips 3 and that of air, or may include a plurality of films having different refractive indices. For example, the anti-reflection layer 7 may include a stack of TiO₂ film, a NB₂O₅ film, and a SiO₂ film with the one having a lower refractive index serving as the outermost film. The anti-reflection layer 7 is disposed to cover on the patterned microstructure 62 of the anti-glare layer 6, so as to reduce total reflection of lights emitted from the micro LED chips 3, thereby increasing the light-emitting efficiency of the COB display device.

The anti-fingerprint layer 8 may be made of a material selected from the group consisting of fluorine-containing compound, silane compound, and a combination thereof. The anti-fingerprint layer 8 is disposed to cover on the anti-reflection layer 7 opposite to the substrate 2, so as to reduce oil residue that remains after a user touches the surface of the COB display device.

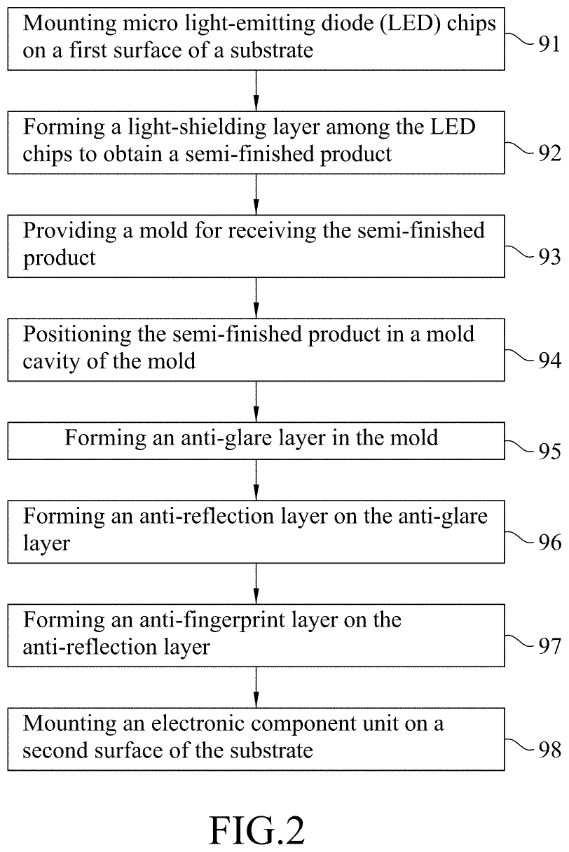

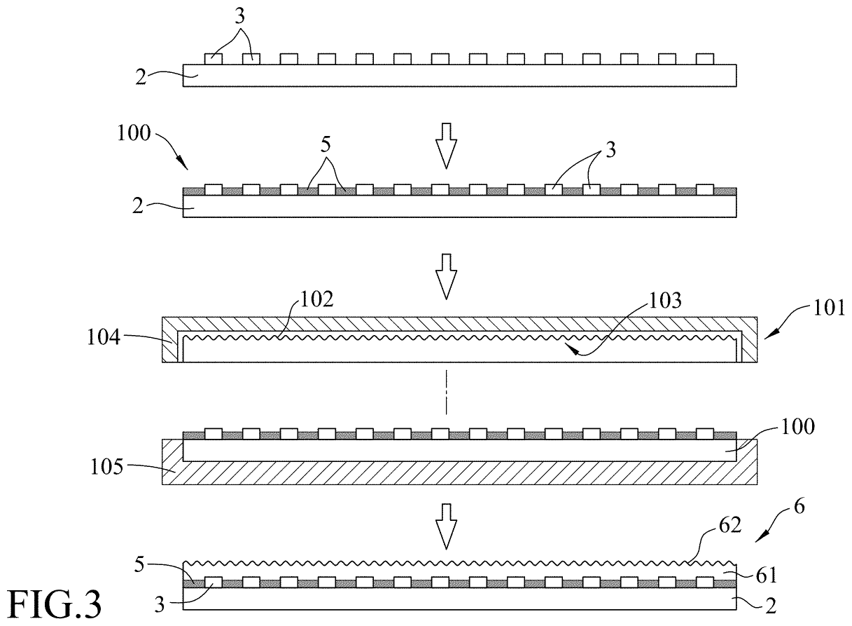

FIGS. 2 and 3 illustrate a method for making the COB display device according to an embodiment of the disclosure. The method includes the following consecutive steps 91 to 98.

In step 91, the micro LED chips 3 spaced apart in an array are mounted on the first surface 21 of the substrate 2 to permit the micro LED chips 3 to define thereamong, the recessed portion. Specifically, the micro LED chips 3 are directly soldered on the first surface 21 of the substrate 2 through a solder material.

In step 92, the light-shielding layer 5 is formed in the recessed portion. Specifically, an opaque polymer material (e.g., a black matrix resin, BM) is filled in the recessed portion by inkjet printing, and is then dried and hardened to form the light-shielding layer 5 therein, so as to obtain the semi-finished product 100.

In step 93, the mold 101 is provided for receiving the semi-finished product 100. Specifically, the mold 101 has a mold-releasing layer 102 which has the micropattern 103 with the concave-convex structure and which is provided for confronting the micro LED chips 3 of the semi-finished product 100. In an embodiment shown in FIG. 3, the mold 101 may include a first mold segment 104 and a second mold segment 105 which cooperatively define a mold cavity therebetween, and the mold-releasing layer 102 may be disposed in the mold cavity to be attached to the first mold segment 104.

In step 94, the semi-finished product 100 is positioned in the mold cavity of the mold 101 in such a manner that the micro LED chips 3 faces the mold-releasing layer 102.

In step 95, the anti-glare layer 6 is formed to cover the micro LED chips 3. Specifically, a light-transmissive optical material is introduced to the mold cavity that is positioned between the semi-finished product 100 and the mold-releasing layer 102, such that the light-transmissive optical material is cured to form an anti-glare body 62 of the anti-glare layer 6 that covers the light-shielding layer 5 and the micro LED chips 3, and such that the micropattern 103 of the mold-releasing layer 102 is transferred to form the patterned microstructure 62 of the anti-glare layer 6.

In step 96, the anti-reflection layer 7 is formed on the anti-glare layer 6 opposite to the substrate 2 by vacuum coating. The vacuum coating may be a low temperature (i.e., lower than 80° C.) vacuum coating, such as evaporative or vapor metal deposition, sputtering, ion plating, and so on.

In an embodiment, the anti-reflection layer 7 may include a plurality of films having different refractive indices, e.g., TiO₂/NB₂O₅/SiO₂.

In step 97, the anti-fingerprint layer 8 is formed on the anti-reflection layer 7 opposite to the anti-glare layer 6 by deposition or vacuum coating (e.g., the above-mentioned low-temperature vacuum coating).

In step 98, the electronic components such as the active elements 41 and/or the passive elements 42 are mounted on the second surface 22 of the substrate 2 opposite to the first surface 21 to permit the electronic components to be electrically connected to at least one portion of the micro LED chips 3, thereby obtaining the COB display device shown in FIG. 1.

Conventionally, a micropattern is required to be formed on an inner surface of the mold 101, so as to form a microstructure on an injection molded body. In addition, a mold releasing agent is required to be coated on the inner surface of the mold 101, so that the microstructure of the injection molded body can be easily released. In this disclosure, with the provision of having the micropattern 103 on the mold-releasing layer 102, the process for making the patterned microstructure 62 of the anti-glare layer 6 is simplified, and by virtue of the mold-releasing layer 102, the patterned microstructure 62 is easily released after the micropattern 103 is transferred to the anti-glare layer 6. Therefore, the method of this disclosure is conducive for releasing the patterned microstructure 62 of the anti-glare layer 6, so as to increase mold application and to prevent the mold from releasing agent residue that might affect the quality of subsequent coating. Moreover, because the anti-reflection layer 7 and/or the anti-fingerprint layer 8 are made using low-temperature vacuum coating, rather than high-temperature (i.e., greater than 150° C.) vacuum coating, the substrate 2 can be prevented from being adversely affected by high temperature, and thus different kinds of substrates can be used in the COB display device of this disclosure.

With the provision of the light-shielding layer 5 being filled in the recessed portion among the micro LED chips 3, and the anti-glare layer 6 being disposed to cover the light-shielding layer 5 and the micro LED chips 3, the COB display device of this disclosure can prevent light leakage and is conferred with an anti-glare function. In addition, by virtue of the anti-reflection layer 7 and the anti-fingerprint layer 8, the COB display device of this disclosure is further conferred with anti-reflection and anti-pollution functions.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A chip on board (COB) display device, comprising:
a substrate including a first surface and a second surface that are opposite to each other;
an array of spaced-apart micro light-emitting diode (LED) chips disposed on said first surface of said substrate to define thereamong, a recessed portion recessed relative to said micro LED chips;
a light-shielding layer made of an opaque polymer material, said light-shielding layer being disposed on said first surface and being filled in said recessed portion; and
an anti-glare layer made of a light-transmissive optical material, and disposed to cover said light-shielding layer and said micro LED chips, said anti-glare layer having a surface which is opposite to said substrate and which is formed with a patterned microstructure.

2. The COB display device of claim 1, further comprising an anti-reflection layer that is disposed to cover on said patterned microstructure of said anti-glare layer.

3. The COB display device of claim 2, wherein said anti-reflection layer has a refractive index ranging between that of a semiconductor material for making the micro LED chips and that of air.

4. The COB display device of claim 2, further comprising an anti-fingerprint layer that is disposed to cover on said anti-reflection layer opposite to said substrate.

5. The COB display device of claim 4, wherein said anti-fingerprint layer is made of a material selected from the group consisting of fluorine-containing compound, silane compound, and a combination thereof.

6. The COB display device of claim 1, wherein said light-shielding layer is filled to a level not higher than that of said micro LED chips.

7. The COB display device of claim 1, wherein said substrate is a circuit board having a control circuit, said micro LED chips being electrically connected to said control circuit.

8. The COB display device of claim 1, further comprising an active element and a passive element that are disposed on said second surface of said substrate and that are in signal connection with said micro LED chips.

9. A method for making a chip on board (COB) display device, comprising the steps of:
a) mounting an array of spaced-apart micro light-emitting diode (LED) chips on a first surface of a substrate to permit the micro LED chips to define thereamong, a recessed portion;
b) filling an opaque polymer material in the recessed portion by inkjet printing to form a light-shielding layer therein, so as to obtain a semi-finished product;
c) providing a mold with a mold-releasing layer which has a micropattern of a concave-convex structure and which is provided for confronting the micro LED chips of the semi-finished product;
d) positioning the semi-finished product in a mold cavity of the mold in such a manner that the micro LED chips faces the mold-releasing layer; and
e) after step d), introducing a light-transmissive optical material to the mold cavity that is positioned between the semi-finished product and the mold-releasing layer, such that the light-transmissive optical material is cured to form an anti-glare layer that covers the light-shielding layer and the micro LED chips, and such that the micropattern of the mold-releasing layer is transferred to form a patterned microstructure of the anti-glare layer.

10. The method of claim 9, after step e), further comprising a step of:
f) forming an anti-reflection layer on the anti-glare layer opposite to the substrate by vacuum coating.

11. The method of claim 10, after step f), further comprising a step of:
g) forming an anti-fingerprint layer on the anti-reflection layer opposite to the anti-glare layer by deposition or vacuum coating.

12. The method of claim 11, wherein the substrate includes a circuit, the micro LED chips being mounted to be electrically connected to the circuit in step a).

13. The method of claim 11, after step g), further comprising a step of:
h) mounting a plurality of electronic components on a second surface of the substrate opposite to the first surface to permit the electronic components to be electrically connected to at least one portion of the micro LED chips.
